(19) United States
(12) Patent Application Publication
(10) Pub. No.: US 2023/0031153 A1
(43) Pub. Date: Feb. 2, 2023

(54) Device Component Assembly And Manufacturing Method Thereof

(71) Applicant: Pin Long, LaSalle (CA)

(72) Inventor: Pin Long, LaSalle (CA)

(21) Appl. No.: 17/391,860

(22) Filed: Aug. 2, 2021

(51) Int. Cl. G02B 27/62; G02B 7/00; H05K 1/02; H05K 3/30

(52) U.S. Cl. CPC G02B 27/62; G02B 7/003; G02B 7/008; H05K 1/0271; H05K 1/0203; H05K 3/305; G02F 1/3503

(57) ABSTRACT

A device component assembly including an upper support plate (USP) of glass and a lower support plate (LSP) of metal affixed to the USP, and a manufacturing method are provided. The USP and the LSP include openings of different shapes and sizes. The LSP includes gaps cut in different directions for reducing thermal expansion and tension generated during a temperature shift. Device components including optical, mechanical, electric, electronic, and optoelectronic components are mutually optically aligned and mounted on the USP and/or the LSP based on component requirements. The device components are mounted on the LSP through the openings of the USP. The optical components are affixed to the support plate(s) using a fastening material. One or more heat transfer members are affixed to the LSP for mounting the device component(s) thereon, after mutual optical alignment therebetween. The device component assembly is integrated in an optical or optoelectronic module or system.

### BACKGROUND

Recent advances in optical and optoelectronic technology have led to increasing complexity in assembling device components such as optical components, electric components, electronic components, and optoelectronic components on a platform for realization of complete modules and systems. The growing number and diversity of constitutive device components emphasize the need for reliable component models and systems. Optical and optoelectronic assemblies include multiple optical components, electric components, electronic components, and optoelectronic components mounted on a platform and configured to assist in constructing optical and optoelectronic systems. For example, some optical and optoelectronic systems utilize a fiber laser as a laser source for pumping a fluoride-based optical fiber glass such as ZrF4-BaF2-LaF3-AlF3-NaF (ZBLAN) made of zirconium, barium, lanthanum, aluminum, and sodium to generate a mid-infrared source. The fiber laser may also be used for second-harmonic generation and fourth-harmonic generation in a complex optoelectronic system comprising, for example, an optical lens, a wave plate, and optoelectronic components such as nonlinear optical or optics crystals and crystal ovens. In another example, a bow-tie structure setup for second-harmonic generation is a complex optoelectronic system comprising optical components such as a lens, a mirror, etc.; optoelectronic components such as a nonlinear optical crystal and a crystal oven, a reflection mirror, etc.; and a mechanical moving stage such as a piezo stage.

An optical assembly is an arrangement of optical components, for example, lenses, mirrors, prisms, etc., aligned and mounted in a manner for guiding an optical beam, for example, a laser beam. An operator may adjust the position and angle of the optical components to guide a laser through a path required. Optical and optoelectronic assemblies, herein exemplarily referred to as “device component assemblies”, contain a combination of assorted components and modules configured to meet many typical optical or optoelectronic needs such as mounting, alignment, beam manipulation, focusing, etc. These device component assemblies require temperature control, heat conductivity, heat diffusion, mechanical movement, precision, accuracy, compactness, portability, and compliance with industry standards. Materials need to be selected carefully for aligning and mounting device components in these device component assemblies.

An optoelectronic system or a module of an optoelectronic system, for example, a second-harmonic generation (SHG) module, a third-harmonic generation (THG) module, or a fourth-harmonic generation (FHG) module, is typically made of an assembly of multiple optical and optoelectronic components such as a focus lens, a half-wave plate, a photonic crystal, a heater, etc., mounted on a metal plate also referred to as a “base plate”. Device component assemblies such as an optoelectronic system assembly or an optoelectronic module assembly typically utilize a metal plate independently as a base plate for mounting all the constitutive device components, that is, the optical, electric, electronic, and optoelectronic components. However, to prevent deformation of the metal plate and avoid misalignment of the device components on the metal plate, the metal plate is required to be substantially thick, thereby increasing the weight of these device component assemblies. Substantially thin metal plates used for mounting all the device components typically get deformed during assembly. Moreover, all the device components are required to be fixed on metal mounts, for example, lens holders, prior to mounting all the device components together on the metal plate. The device components along with their metal mounts affixed to the metal plate increase the size and bulkiness of the device component assemblies. Furthermore, the cost of these device components along with their metal mounts affixed to the metal plate is substantially high.

Alternative to a metal plate, some device component assemblies utilize a glass plate independently for mounting all the device components because of properties such as rigidity, bend resistance, and low thermal expansion of glass. Glass plates are typically used for mounting small sized optical components. However, a glass plate cannot be used for mounting device components when one or more optical components need a heat sink or one or more optoelectronic components need temperature control. There is a need to manage thermal behavior in a device component assembly to enhance integration and performance of the device components. Moreover, the glass plate is not suitable for applications where there is a need for assembling optical components, electric components, and electronic components, for example, a crystal oven, together, due to the poor heat diffusion capability of glass. Furthermore, when an optical component needs a large mechanical movement using one-dimensional or two-dimensional linear moving stages, the glass plate is not suitable for mounting large metal moving stages.

Hence, there is a long-felt need for a compact device component assembly and a manufacturing method thereof, where multiple device components, for example, optical components, mechanical components, electric components, electronic components, and optoelectronic components, are mutually optically aligned and mounted together on one or more support plates made of different materials based on different component requirements. Furthermore, there is a need for a compact device component assembly that accommodates mutually optically aligned device components for construction of optical and optoelectronic modules and/or systems for implementing multiple optical processes, for example, non-linear optical processes such as second-harmonic generation, third-harmonic generation, fourth-harmonic generation, optical parametric oscillation, optical parametric amplification, sum-frequency generation, difference-frequency generation, etc., using the mutually optically aligned device components in the device component assembly.

### SUMMARY

This summary is provided to introduce a selection of concepts in a simplified form that are further disclosed in the detailed description. This summary is not intended to determine the scope of the claimed subject matter.

The system and the method disclosed herein address the above-recited need for a device component assembly and a manufacturing method thereof, where multiple device components, for example, optical components, mechanical components, electric components, electronic components, and optoelectronic components are mutually optically aligned and mounted together on one or more support plates made of different materials, for example, glass, metal, etc., based on different component requirements. As used herein, “device component assembly” refers to an optical assembly, or an optoelectronic assembly, or a combination thereof. The device component assembly allows multiple device components, for example, temperature-controlled chambers such as crystal ovens, to be mounted together on support plates made of different materials. The device component assembly manages thermal behavior, thereby enhancing integration and performance of the device components mounted thereon. The compact device component assembly disclosed herein accommodates mutually optically aligned device components for construction of optical and optoelectronic modules and/or systems for implementing multiple optical processes, for example, nonlinear optical processes such as second-harmonic generation, third-harmonic generation, fourth-harmonic generation, optical parametric oscillation, optical parametric amplification, sum-frequency generation, difference-frequency generation, etc., using the mutually optically aligned device components in the device component assembly. For example, multiple mutually optically aligned device components comprising optical components such as an optical lens, a wave plate, etc., and optoelectronic components such as nonlinear optical or optics crystals and crystal ovens, are mounted in the device component assembly for construction of optical and optoelectronic systems for second-harmonic generation and fourth-harmonic generation using a fiber laser. In another example, the device component assembly is configured for construction of an optoelectronic system with a bow-tie structure setup for second-harmonic generation comprising optical components such as a lens, a mirror, etc., optoelectronic components such as a nonlinear optical crystal and a crystal oven, a reflection mirror, etc., and a mechanical component such as piezo stage.

The device component assembly comprises an upper support plate made of a first material, a lower support plate made of a second material, and multiple device components. The first material of the upper support plate is selected from hard materials having low thermal expansion and that maintain mutual optical alignment of the device components during a temperature change. The hard materials comprise, for example, a glass material, an artificial glass material, a ceramic material, sapphire, quartz, diamond, etc. The second material of the lower support plate is a metal, for example, aluminum, stainless steel, or other metals having a heat diffusion capability and mechanical stability. The upper support plate comprises first openings of different shapes and sizes positioned at predetermined locations on the upper support plate. In an embodiment, the upper support plate comprises circular openings positioned at the corners of the upper support plate and one or more rectangular openings positioned at other predetermined locations on the upper support plate. The lower support plate is cut in a size corresponding to a size of the upper support plate. In an embodiment, the lower support plate is cut in a size equal to the size of the upper support plate. In another embodiment, the lower support plate is cut in a size greater than the size of the upper support plate. The lower support plate comprises second openings of different shapes and sizes positioned at predetermined locations on the lower support plate. In an embodiment, the lower support plate comprises circular openings positioned at the corners of the lower support plate corresponding to the circular openings positioned at the corners of the upper support plate for inserting fasteners, for example, screws with rubber or plastic washers. The lower support plate further comprises gaps cut therein in different directions at predetermined locations proximal to the predetermined locations of the first openings of the upper support plate. The gaps in the lower support plate are configured to reduce thermal expansion of the lower support plate affixed to the upper support plate. In an embodiment, the gaps comprise at least one linear narrow gap in the lower support plate, positioned between two fixed points, for example, between two openings, in the upper support plate, to avoid tension generated by the affixed lower support plate during a temperature shift. The lower support plate is affixed proximal to a lower surface of the upper support plate using the fasteners, for example, screws with rubber or plastic washers.

The device component assembly is configured to accommodate multiple device components comprising, for example, optical components, mechanical components, electric components, electronic components, and optoelectronic components. One or more of the device components are configured to be mutually optically aligned and mounted on the upper support plate and/or the lower support plate based on component requirements. The component requirements comprise, for example, heat conductivity, temperature control, a heat sink, heat diffusion, mechanical movement, mechanical stability, electronic device connection, compactness, weight, thickness, space, size, rigidity, cost, etc. One or more of the device components are mounted on the lower support plate through one or more of the first openings of the upper support plate. In an embodiment, one or more of the optical components are mounted on the upper support plate made of glass, and one or more of the mechanical components, the electric components, the electronic components, and the optoelectronic components are mounted on the lower support plate made of metal through one or more of the first openings of the upper support plate. One or more of the optical components are affixed to the upper support plate using a fastening material. The fastening material is selected, for example, from one of an epoxy, an ultraviolet epoxy, an epoxy-based composite material, a glue, any adhesive material, and any soldering material.

In an embodiment, one or more of the optical components are mounted on and affixed to the lower support plate via one or more mechanical components, for example, mechanical or motorized moving stages such as piezo stages; or electric components, for example, heaters; or electronic components. One or more of the mechanical components, the electric components, the electronic components, and the optoelectronic components are configured to accommodate one or more of the optical components for mounting the optical components on the lower support plate. In this embodiment, the optical component(s) is affixed to the mechanical, or electric, or electronic component using a fastening material, for example, one of an epoxy, an ultraviolet epoxy, an epoxy-based composite material, a glue, any adhesive material, and any soldering material. The mechanical, or electric, or electronic component with the affixed optical component(s) is then affixed to the lower support plate using fasteners, for example, screws with rubber or plastic washers. The mechanical, electric, or electronic components with the affixed optical components are affixed to the lower support plate through the first openings in the upper support plate. The device components mounted on the upper support plate and the lower support plate are mutually optically aligned on the upper support plate and the lower support plate using an optical beam, for example, a laser beam.

In an embodiment, the device component assembly further comprises one or more heat transfer members, for example, a crystal oven, configured to be affixed to an upper surface of the lower support plate for mounting one or more of the device components on the lower support plate, after mutual optical alignment between the device components. The heat transfer members are configured to transfer heat generated by the mounted device components to the lower support plate. The mounting of one or more of the device components on the lower support plate through one or more of the first openings of the upper support plate allows transfer of heat generated by the device components to the lower support plate, while maintaining mutual optical alignment of the device components having large optical apertures with other device components during a temperature shift.

Disclosed herein is also a method for manufacturing the device component assembly disclosed above. In the method disclosed herein, an upper support plate, for example, a glass plate, of a predetermined size is configured with first openings of different shapes and sizes positioned at predetermined locations on the upper support plate. A lower support plate, for example, a metal plate, of a predetermined size corresponding to the predetermined size of the upper support plate is configured with second openings of different shapes and sizes positioned at predetermined locations on the lower support plate. Multiple gaps are configured in different directions at predetermined locations on the lower support plate, proximal to the predetermined locations of the first openings of the upper support plate. The lower support plate is affixed proximal to a lower surface of the upper support plate using fasteners. One or more device components comprising optical components, mechanical components, electric components, electronic components, and optoelectronic components are mutually optically aligned and mounted on the upper support plate and/or the lower support plate based on component requirements as disclosed above. One or more of the device components, for example, the optical components, are mounted on and affixed to the upper support plate and/or the lower support plate using a fastening material. One or more of the device components, for example, the mechanical components, the electric components, the electronic components, and the optoelectronic components are mounted on and affixed to the lower support plate through one or more of the first openings of the upper support plate using fasteners, for example, screws with rubber or plastic washers. In an embodiment, one or more of the optical components are affixed to the lower support plate via one or more of the mechanical components, or the electric components, or the electronic components as disclosed above. In an embodiment, one or more heat transfer members are affixed to an upper surface of the lower support plate for mounting one or more of the device components on the lower support plate, after mutual optical alignment between the device components.

The manufacturing method disclosed herein provides a method for assembling optical components on the upper support plate made of glass, herein referred to as the “glass plate”, comprising openings of different sizes and shapes, and electronic devices such as crystal ovens on the lower support plate made of metal, herein referred to as the “metal plate”, affixed underneath the glass plate. Moreover, the manufacturing method disclosed herein provides a method for fixing the glass plate on the metal plate having long narrow gaps and screw mounting openings. Furthermore, the manufacturing method disclosed herein provides a method for alignment and assembly of optical components with large metal mounts such as moving stages on the metal plate and other optical components on the glass plate. Furthermore, the manufacturing method disclosed herein provides a method for fixing optical components on the glass plate with a fastening material such as epoxy and for mounting optoelectronic components with metal fixtures on the metal plate. Optical components such as optical lenses, wave plates, mirrors, etc., are mounted on and affixed to the glass plate with glass blocks using epoxy or a glass soldering material after mutual optical alignment between the optical components. Optoelectronic components, for example, ovens containing photonic crystals such as periodically poled lithium niobate (PPLN) crystals, beta barium borate (BBO) crystals, etc., are mounted on the metal plate through the openings of the glass plate and affixed to the metal plate using fasteners, for example, screws and rubber or plastic washers, after mutual optical alignment between the optical components and the optoelectronic components. Because the glass plate has low thermal expansion during a temperature change, the optical components maintain optical alignment during a temperature shift. The optoelectronic components mounted on the metal plate also maintain optical alignment with the optical components mounted on the glass plate because the optoelectronic components have large optical apertures and a small shift of their positions will not cause misalignment optically.

The device component assembly is configured to be integrated in an optical or optoelectronic system or a module of an optical or optoelectronic system for wavelength conversion. For example, the device component assembly is configured to be integrated in a second-harmonic generation (SHG) module, a third-harmonic generation (THG) module, and/or a fourth-harmonic generation (FHG) module. In the device component assembly disclosed herein, all the device components mounted on the upper support plate are mutually optically aligned with each other and with all the device components mounted on the lower support plate for constructing an optical or optoelectronic system or a module of an optical or optoelectronic system, for example, an SHG module, a THG module, an FHG module, an optical parametric oscillator, an optical parametric amplifier, a sum-frequency generator, a difference-frequency generator, and other optical components and modules, mechanical parts and modules, and electronic components and modules integrating systems. The device component assembly, therefore, allows implementation of multiple optical processes, for example, nonlinear optical processes such as second-harmonic generation, third-harmonic generation, fourth-harmonic generation, optical parametric oscillation, optical parametric amplification, sum-frequency generation, difference-frequency generation, etc.

In one or more embodiments, related systems comprise circuitry for executing the methods disclosed herein. The circuitry is of any combination of hardware, software, and/or firmware configured to execute the methods disclosed herein depending upon the design choices of a system designer. In an embodiment, various structural elements are employed depending on the design choices of the system designer.

### BRIEF DESCRIPTION OF THE DRAWINGS

The foregoing summary, as well as the following detailed description, is better understood when read in conjunction with the appended drawings. For illustrating the embodiments herein, exemplary constructions of the embodiments are shown in the drawings. However, the embodiments herein are not limited to the specific components, structures, and methods disclosed herein. The description of a component, a structure, and a method step referenced by a numeral in a drawing is applicable to the description of that component, structure, or method step shown by that same numeral in any subsequent drawing herein.

FIG. 1A exemplarily illustrates an exploded, top perspective view of a device component assembly for an optoelectronic system, according to an embodiment herein.

FIG. 1B exemplarily illustrates an assembled, top perspective view of the device component assembly for the optoelectronic system shown in FIG. 1A.

FIG. 1C exemplarily illustrates a bottom perspective view of the device component assembly shown in FIG. 1B, showing openings and gaps configured in a lower support plate of the device component assembly.

FIG. 2 exemplarily illustrates a top perspective view showing an optical component mounted on a mounting member and affixed to an upper surface of an upper support plate of the device component assembly using a fastening material.

FIG. 3 exemplarily illustrates a top perspective view of an optoelectronic component mounted on a heat transfer member and configured to be affixed to an upper surface of the lower support plate through an opening of the upper support plate of the device component assembly.

FIG. 4A exemplarily illustrates a top perspective view of a device component assembly for another optoelectronic system, according to an embodiment herein.

FIG. 4B exemplarily illustrates a top plan view of the device component assembly for the optoelectronic system shown in FIG. 4A.

FIG. 5 exemplarily illustrates a top perspective view of a device component assembly for another optoelectronic system, according to an embodiment herein.

FIG. 6 illustrates a flowchart of a method for manufacturing a device component assembly, according to an embodiment herein.

### DETAILED DESCRIPTION

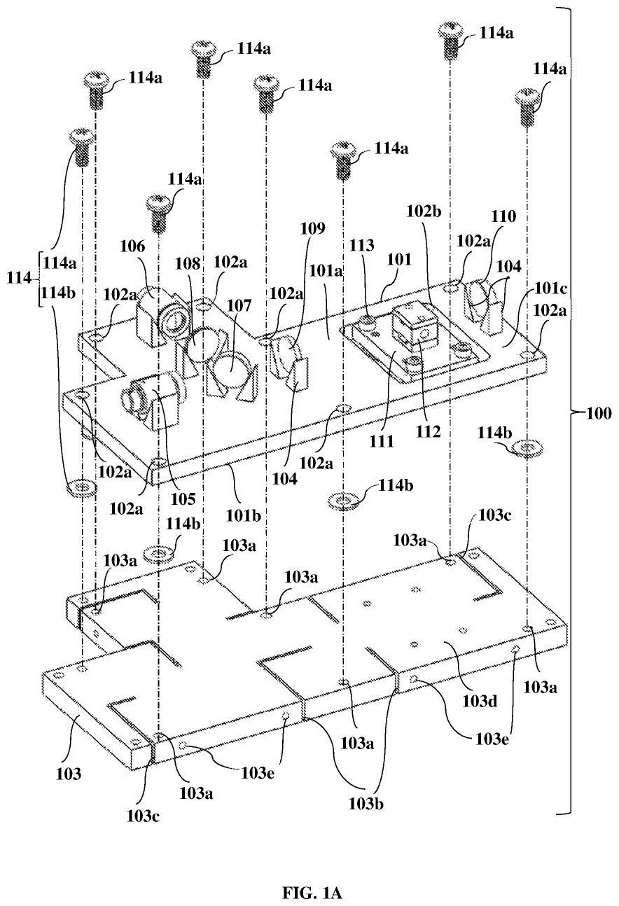

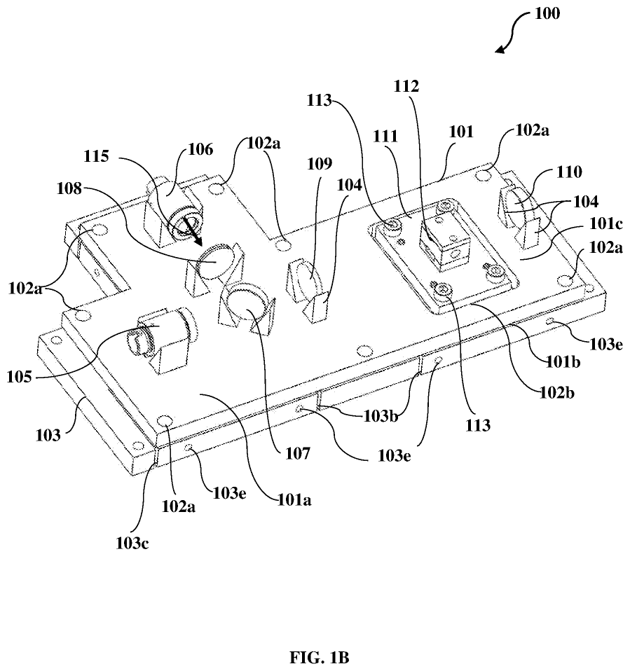

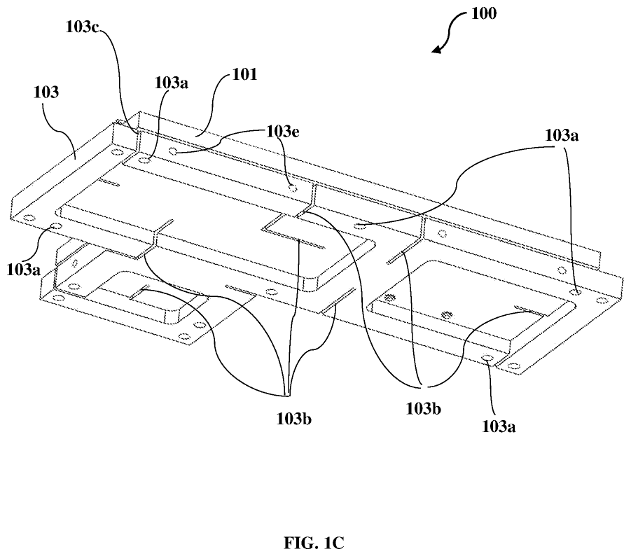

FIG. 1A exemplarily illustrates an exploded, top perspective view of a device component assembly 100 for an optoelectronic system, according to an embodiment herein. As used herein, “device component assembly” refers to an optical assembly, or an optoelectronic assembly, or a combination thereof. An optical assembly is an assembly of optical components, for example, focus lenses, mirrors, prisms, diffraction gratings, optical collimators, harmonic separators, beam splitters, wave plates, polarizers, etc., configured for integration in optical systems or modules of optical systems for different optical applications such as laser technology, microscopy, imaging, fiber optics, etc. Optical components alter the state of light through different methods comprising, for example, focusing, filtering, reflecting, or polarizing. Some optical components require mechanical movement that is actuated using mechanical components, for example, one-dimensional or two-dimensional moving stages. Some optical components require electric components, for example, heaters, for modulating the optical and thermal response of the optical components. An optoelectronic assembly is an assembly of electric, electronic, and optoelectronic components, that is, components that create, manipulate, and detect light by expending electrical energy. The optoelectronic components comprise, for example, ovens containing photonic crystals such as periodically poled lithium niobate (PPLN) crystals, lithium triborate (LiB₃O₅) or LBO crystals, beta barium borate (BBO) crystals, etc., light emitting diodes (LEDs), laser diodes, photodiodes, phototransistors, imaging detectors, photonic integrated circuits, optocouplers, etc., configured for integration in optoelectronic systems or modules of optoelectronic systems for different optoelectronic applications such as optical fiber communications, laser technology, optical metrology, etc. The optical components, the mechanical components, the electric components, the electronic components, and the optoelectronic components are herein collectively referred to as “device components”.

The device component assembly 100 comprises an upper support plate 101 made of a first material, a lower support plate 103 made of a second material, and multiple device components, for example, 105, 106, 107, 108, 109, 110, 112, etc., as exemplarily illustrated in FIG. 1A. The first material of the upper support plate 101 is selected from hard materials having low thermal expansion and that maintain mutual optical alignment of the device components during a temperature change. As used herein, “optical alignment” refers to an arrangement of two or more optical or optoelectronic components in optical communication allowing for transmission or transfer of a majority of light between them. The hard materials used for manufacturing the upper support plate 101 comprise, for example, a glass material, an artificial glass material, a ceramic material, sapphire, quartz, diamond, etc. The thickness of the upper support plate 101 is, for example, more than about 5 millimeters (mm) to prevent bending of the upper support plate 101. The second material of the lower support plate 103 is a metal, for example, aluminum, stainless steel, or other metals having a heat diffusion capability and mechanical stability.

The upper support plate 101 comprises first openings 102a and 102b of different shapes and sizes positioned at predetermined locations on the upper support plate 101. In an embodiment, the upper support plate 101 comprises circular openings 102a positioned at the corners of the upper support plate 101 and one or more rectangular openings 102b positioned at other predetermined locations on the upper support plate 101. The lower support plate 103 is cut in a size corresponding to a size of the upper support plate 101. In an embodiment, the lower support plate 103 is cut in a size equal to the size of the upper support plate 101. In another embodiment, the lower support plate 103 is cut in a size greater than the size of the upper support plate 101. The lower support plate 103 comprises second openings 103a and 103e of different shapes and sizes positioned at predetermined locations on the lower support plate 103. In an embodiment, the lower support plate 103 comprises circular openings 103a positioned at the corners of the lower support plate 103 corresponding to the circular openings 102a positioned at the corners of the upper support plate 101 for inserting fasteners, for example, screws 114a. The circular openings 102a positioned at the corners of the upper support plate 101 are coaxial to the circular openings 103a positioned at the corresponding corners of the lower support plate 103 for allowing insertion of the screws 114a used to affix the lower support plate 103 to the upper support plate 101. In an embodiment, the lower support plate 103 comprises supplementary openings 103e configured, for example, as threaded holes, positioned along a periphery of the lower support plate 103 for fixing a protective cover (not shown). In an embodiment, the protective cover is used for protecting the device component assembly 100 from particulate matter, for example, dust. The protective cover is fastened to the lower support plate 103 by inserting fasteners (not shown), for example, screws, into openings in the protective cover and the corresponding supplementary openings 103e of the lower support plate 103.

The lower support plate 103 further comprises gaps 103b and 103c cut therein in different directions, for example, a horizontal direction, a vertical direction, etc., at predetermined locations proximal to the predetermined locations of the first openings 102a of the upper support plate 101. In an embodiment, the gaps 103b are positioned in the lower support plate 103 between fasteners 114 used to fix the lower support plate 103 below the upper support plate 101. The gaps 103b between two fasteners, for example, screws 114a, prevent the tension between the upper support plate 101 and the lower support plate 103 having different thermal expansion coefficients. If an optoelectronic system constructed from the device component assembly 100 is placed outside a building, the temperature of the optoelectronic system may change, for example, from about −20 degrees Celsius (C) to about +50 degrees C., while inside a building, the temperature of the optoelectronic system may change, for example, from about 0 degree C. in the evening to about 25 degrees C. at noon. The gaps 103b and 103c in the lower support plate 103 of the device component assembly 100 are configured to reduce thermal expansion of the lower support plate 103 affixed to the upper support plate 101 and tension generated by the affixed lower support plate 103 during a temperature shift or a temperature change. There is at least one linear narrow gap 103b in the lower support plate 103 between two fixed points, for example, between two holes or openings 102a, in the upper support plate 101 affixed to the lower support plate 103 to avoid the tension caused by the temperature shift.

The lower support plate 103 is affixed proximal to a lower surface 101b of the upper support plate 101 using the fasteners 114. In an embodiment, the fasteners 114 comprise, for example, screws 114a and washers 114b. The screws 114a are inserted through the corresponding openings 102a and 103a of the upper support plate 101 and the lower support plate 103 respectively. The washers 114b, for example, rubber or plastic washers, are positioned below the upper support plate 101, that is, below the circular openings 102a of the upper support plate 101 and above the circular openings 103a of the lower support plate 103. The washers 114b are coaxially aligned with the circular openings 102a of the upper support plate 101 and the corresponding circular openings 103a of the lower support plate 103. The screws 114a are inserted through the circular openings 102a of the upper support plate 101, the respective washers 114b, and the circular openings 103a of the lower support plate 103 for fastening the lower support plate 103 to the upper support plate 101. The washers 114b distribute the load of the screws 114a. After affixing the lower support plate 103 to the upper support plate 101 using the fasteners 114, the washers 114b lie flush between the lower surface 101b of the upper support plate 101 and the upper surface 103d of the lower support plate 103.

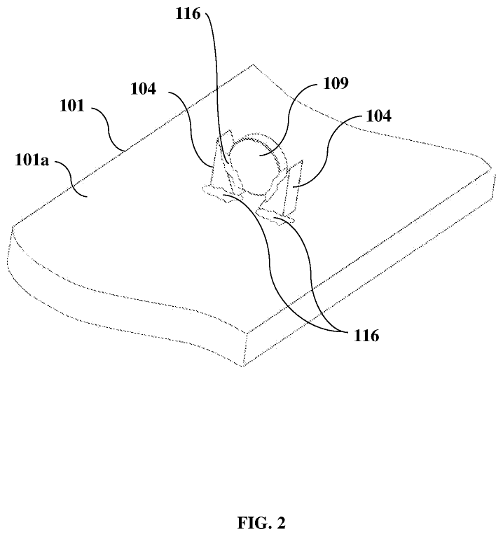

The device component assembly 100 is configured to accommodate multiple device components comprising, for example, optical components, mechanical components, electric components, electronic components, and optoelectronic components. One or more of the device components, for example, 105, 106, 107, 108, 109, 110, 111, 112, etc., are configured to be mutually optically aligned and mounted on the upper support plate 101 and/or the lower support plate 103 based on component requirements. The component requirements comprise, for example, heat conductivity, temperature control, a heat sink, heat diffusion, mechanical movement, mechanical stability, electronic device connection, compactness, weight, thickness, space, size, rigidity, cost, etc. One or more of the device components, for example, 111 and 112, are mounted on the lower support plate 103 through one or more of the first openings, for example, 102b, of the upper support plate 101. In an embodiment, one or more of the optical components, for example, 105, 106, 107, 108, 109, and 110, are mounted on the upper support plate 101, and one or more of the mechanical components, the electric components, the electronic components, and the optoelectronic components, for example, 111 and 112, are mounted on the lower support plate 103 through one or more of the first openings, for example, 102b, of the upper support plate 101. One or more of the optical components, for example, 105, 106, 107, 108, 109, and 110, are affixed to the upper surface 101a of the upper support plate 101 using a fastening material 116 exemplarily illustrated in FIG. 2. The fastening material 116 is selected, for example, from one of an epoxy, an ultraviolet epoxy, an epoxy-based composite material, a glue, any adhesive material, and any soldering material. In an embodiment, the optical components for example, 105, 106, 107, 108, 109, and 110 are mounted on mounting members, for example, glass blocks 104, which are then affixed to the upper surface 101a of the upper support plate 101 using the fastening material 116 as exemplarily illustrated in FIG. 2.

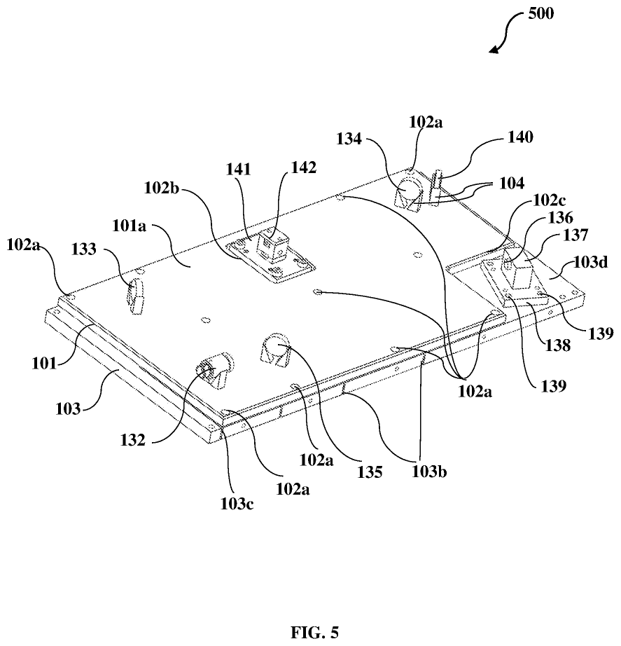

In an embodiment, one or more of the mechanical components, the electric components, the electronic components, and the optoelectronic components are configured to accommodate one or more of the optical components, for example, 136, for mounting the optical component(s) 136 on the lower support plate 103 as exemplarily illustrated in FIG. 5. For example, an optical component 136 is mounted on the lower support plate 103 via a mechanical component, for example, a mechanical or motorized moving stage 137 such as a piezo stage as exemplarily illustrated in FIG. 5. In this embodiment, the optical component 136 is affixed to the mechanical or motorized moving stage 137, for example, the piezo stage, using a fastening material 116 exemplarily illustrated in FIG. 2. The mechanical or motorized moving stage 137 with the affixed optical component 136 is then affixed to the lower support plate 103 using fasteners 139, for example, screws with rubber or plastic washers. In another embodiment, one or more of the optical components are mounted on the lower support plate 103 via one or more electric components, for example, heaters (not shown). In this embodiment, the optical component(s) is affixed to the heater using a fastening material 116. The heater with the affixed optical component(s) is then affixed to the lower support plate 103 using fasteners (not shown), for example, screws with rubber or plastic washers. In an embodiment, the mechanical, electric, or electronic components with the affixed optical components are affixed to the lower support plate 103 through the openings, for example, 102c, in the upper support plate 101 as exemplarily illustrated in FIG. 5.

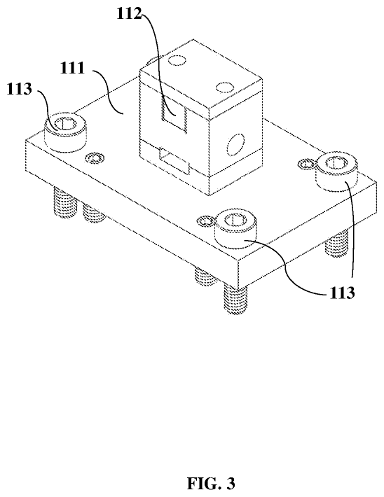

In an embodiment, the device component assembly 100 further comprises one or more heat transfer members, for example, a crystal oven 111, configured to be affixed to an upper surface 103d of the lower support plate 103 for mounting one or more of the device components, for example, 112, on the lower support plate 103, after mutual optical alignment between the device components, for example, 105, 106, 107, 108, 109, 110, 112, etc. The heat transfer members are configured to transfer heat generated by the mounted device component(s), for example, 112, to the lower support plate 103. The mounting of one or more of the device components, for example, 112, on the lower support plate 103 through one or more of the first openings, for example, 102b, of the upper support plate 101 allows transfer of heat generated by the device component(s) 112 to the lower support plate 103, while maintaining mutual optical alignment of the device component(s) 112 having a large optical aperture exemplarily illustrated in FIG. 3, with one or more of the other device components, for example, 109 and 110, during a temperature shift.

The optical components and the optoelectronic components, for example, 105, 106, 107, 108, 109, 110, 111, 112, etc., mounted on the upper support plate 101 and the lower support plate 103 are mutually optically aligned on the upper support plate 101 and the lower support plate 103 using an optical beam 115, for example, a light beam or a laser beam exemplarily illustrated in FIG. 1B. Optical alignment comprises adjustable positioning of an optical assembly relative to one or more optoelectronic components to align an optical axis of a respective optical component of the optical assembly to an optical axis of a corresponding optical component of the optoelectronic component to minimize optical signal attenuation between the optoelectronic component and the optical assembly to within an acceptable tolerance. The device components, for example, 105, 106, 107, 108, 109, and 110 mounted on the upper support plate 101 are mutually optically aligned with each other and with the device components, for example, 111 and 112, mounted on the lower support plate 103 for constructing an optical system, or an optoelectronic system, or a module of an optical system or an optoelectronic system, for example, a second-harmonic generation (SHG) module, a third-harmonic generation (THG) module, a fourth-harmonic generation (FHG) module, an optical parametric oscillator, an optical parametric amplifier, a sum-frequency generator, a difference-frequency generator, and other optical components and modules, mechanical parts and modules, and electronic components and modules integrating system. The device component assembly 100, therefore, allows implementation of multiple optical processes, for example, nonlinear optical processes such as second-harmonic generation, third-harmonic generation, fourth-harmonic generation, optical parametric oscillation, optical parametric amplification, sum-frequency generation, difference-frequency generation, etc. Second-harmonic generation, also referred to as frequency doubling, is a nonlinear optical process where an input wave, for example, in the form of a laser beam, in a nonlinear material generates a wave with twice the frequency, that is, half the wavelength in the nonlinear material. The SHG module generates the frequency-doubled wave, also referred to as a “second-harmonic wave”, in the form of a beam propagating in a similar direction as that of the input wave. The THG module generates light at a wavelength which is ⅓rd of the pump wavelength using a two-stage interaction, where the first stage is a second-harmonic generation of a pumping laser and the second stage is a sum-frequency generation of the pump and second harmonic, yielding the third harmonic. The FHG module is a frequency converter that quadruples the frequency of ultrashort pulse lasers. The FHG module generates light at a wavelength that is quarter (¼) of the pump wavelength. Fourth-harmonic generation occurs through a two-stage nonlinear interaction, where the first stage comprises doubling of the pumping laser, followed by the second stage comprising a second-harmonic generation of the generated wavelength. Optical parametric oscillation refers to a nonlinear optical process of generating a signal and an idler wave using a parametric amplifier in a resonator with no signal input. Optical parametric amplification refers to a nonlinear optical process of amplifying a signal input in the presence of a higher-frequency pump wave based on a parametric nonlinearity, while simultaneously generating an idler wave. Sum-frequency generation refers to a nonlinear optical process of generating light with a frequency that is the sum of two input frequencies. Difference-frequency generation refers to a nonlinear optical process of generating light with a frequency that is the difference between two input frequencies.

FIG. 1B exemplarily illustrates an assembled, top perspective view of the device component assembly 100 for the optoelectronic system shown in FIG. 1A. Consider an example where the device component assembly 100 is integrated in an optical setup for double-pass second-harmonic generation using a nonlinear optics or optical crystal 112 such as lithium triborate (LiB₃O₅) also referred to as LBO as exemplarily illustrated in FIG. 1B. In this example, the device component assembly 100 comprises an upper support plate 101 made of glass, herein referred to as a “glass plate”, and a lower support plate 103 made of metal, for example, aluminum, herein referred to as a “metal plate”. For purposes of illustration, the detailed description refers to the upper support plate 101 as being a “glass plate”; however, the scope of the device component assembly 100 and the manufacturing method disclosed herein is not limited to the upper support plate 101 being a glass plate, but may be extended to include the upper support plate 101 being made of any hard material, for example, an artificial glass material, a ceramic material, sapphire, quartz, diamond, etc., that has low thermal expansion and maintains optical alignment of the device components during a temperature change.

As exemplarily illustrated in FIG. 1B, the glass plate 101 comprises holes or openings, for example, circular openings 102a positioned at the corners of the glass plate 101 and one rectangular opening 102b positioned at an extended rectangular section 101c of the glass plate 101. The circular openings 102a at the corners of the glass plate 101 are used for inserting fasteners 114, for example, screws 114a with washers 114b as exemplarily illustrated in FIG. 1A, to affix the metal plate 103 to the glass plate 101. The rectangular opening 102b is used for mounting an optoelectronic component, for example, a nonlinear optical crystal 112, therethrough and affixing the nonlinear optical crystal 112 to the metal plate 103 via a crystal oven 111. The nonlinear optical crystal 112 is affixed to the crystal oven 111, which is affixed to the upper surface 103d of the metal plate 103 through the rectangular opening 102b of the glass plate 101.

In an embodiment as exemplarily illustrated in FIGS. 1A-1B, the metal plate 103 is cut in a size greater than the size of the glass plate 101. The metal plate 103 comprises holes or openings, for example, circular openings 103a positioned at the corners of the metal plate 103, coaxial to the circular openings 102a at the corners of the glass plate 101 for inserting the fasteners, for example, screws 114a, to affix the metal plate 103 to the glass plate 101. The metal plate 103 further comprises gaps 103b and 103c cut therein in horizontal and vertical directions at predetermined locations proximal to the openings 102a of the glass plate 101. For example, the metal plate 103 comprises gaps 103b cut in a vertical direction between the openings 102a of the glass plate 101 as exemplarily illustrated in FIGS. 1A-1B. The metal plate 103 further comprises a gap 103c positioned at the edge of the metal plate 103 and outside the glass plate 101. The glass plate 101 is configured to be mounted on top of the metal plate 103 such that the circular openings 102a of the glass plate 101 are coaxially aligned with the circular openings 103a of the metal plate 103 as exemplarily illustrated in FIG. 1A.

Optical components, for example, an optical focus lens 109, an optical focus mirror 110, fiber collimators 105 and 106, a half-wave plate 108, and a harmonic separator 107 are mounted on and affixed to the glass plate 101. A nonlinear optical crystal 112, for example, a lithium triborate or LBO crystal, is positioned on and attached to a crystal oven 111, which is mounted on and affixed to the metal plate 103 through the rectangular opening 102b of the glass plate 101. After optical alignment using an optical beam 115, for example, a laser beam, the optical focus lens 109, the optical focus mirror 110, the fiber collimators 105 and 106, the half-wave plate 108, and the harmonic separator 107 are affixed to the glass plate 101 using mounting members, for example, glass blocks 104, and a fastening material 116, for example, ultraviolet epoxy, exemplarily illustrated in FIG. 2; and the nonlinear optical crystal 112 mounted on the crystal oven 111 is affixed to the metal plate 103 using fasteners 113, for example, four screws and a spring washer. The glass plate 101 is then affixed to the metal plate 103 using, for example, the screws 114a inserted through the coaxial, circular openings 102a and 103a. The screws 114a are inserted through the coaxially aligned circular openings 102a and 103a of the glass plate 101 and the metal plate 103 respectively, with the respective washers 114b positioned firmly between the glass plate 101 and the metal plate 103 as disclosed in the detailed description of FIG. 1A. Because most of the optical components, for example, 105, 106, 107, 108, 109, and 110 are mounted on the glass plate 101 which has a substantially low thermal expansion, the optical beam 115 emitted from the fiber collimator 106 passes through the same positions at each of the optical components 107, 108, 109, and 110 on the glass plate 101 and maintains its optical alignment during a temperature change. Since the nonlinear optical crystal 112 on the crystal oven 111 has a large effective optical aperture, the optical beam 115 emitted from the collimator 106 passes through the optical aperture of the nonlinear optical crystal 112 but at a slightly different position caused by the crystal oven 111 that is mounted on the metal plate 103 having a minimal deformation or displacement due to a temperature shift. The crystal oven 111 mounted on the metal plate 103 substantially diffuses the heat generated by the nonlinear optical crystal 112 to the metal plate 103.

FIG. 1C exemplarily illustrates a bottom perspective view of the device component assembly 100 shown in FIG. 1B, showing the openings 103a and the gaps 103b and 103c configured in the lower support plate 103 of the device component assembly 100. The gaps 103b and 103c are cut in vertical and horizontal directions in the lower support plate 103 proximal to the openings 102a of the upper support plate 101. In an embodiment, the locations of the gaps 103b in the lower support plate 103 are at fixed positions with respect to the fasteners 114, that is, the screws 114a and the rubber or plastic washers 114b. Because the lower support plate 103 made of metal and the upper support plate 101 made of glass have different thermal expansion coefficients, the gaps 103b and 103c prevent the tension between the upper support plate 101 and the lower support plate 103 during temperature changes. In an embodiment, the gaps 103b are positioned between two circular openings 103a configured, for example, as threaded holes, as exemplarily illustrated in FIG. 1C. The circular openings 103a in the lower support plate 103 positioned coaxial to the circular openings 102a in the upper support plate 101 exemplarily illustrated in FIGS. 1A-1B, are used for mounting and affixing the upper support plate 101 on the lower support plate 103 with the fasteners 114, for example, the screws 114a and the rubber or plastic washers 114b. The gap 103c of the lower support plate 103 positioned proximal to the edge of the upper support plate 101 is used to prevent tension between the upper support plate 101 and the lower support plate 103, when the lower support plate 103 is affixed to another structure, for example, a base plate of an enclosure.

FIG. 2 exemplarily illustrates a top perspective view showing an optical component mounted on a mounting member and affixed to an upper surface 101a of the upper support plate 101 of the device component assembly 100 shown in FIGS. 1A-1B, using a fastening material 116. After all the optical components, for example, 105, 106, 107, 108, 109, 110, etc., of the device component assembly 100 are mutually optically aligned to each other using an optical beam 115 as exemplarily illustrated in FIG. 1B, the optical components 105, 106, 107, 108, 109, 110, etc., are affixed to the upper surface 101a of the upper support plate 101 using a fastening material 116, for example, any one of an epoxy, an ultraviolet epoxy, an epoxy-based composite material, a glue, an adhesive material, a soldering material, etc. FIG. 2 exemplarily illustrates the fixing of one of the optical components, for example, the optical focus lens 109, to the upper surface 101a of the upper support plate 101 of the device component assembly 100. The optical focus lens 109 is first affixed to a mounting member, for example, glass blocks 104, using the fastening material 116, for example, an ultraviolet epoxy. The glass blocks 104 with the mounted optical focus lens 109 are then affixed to the upper surface 101a of the upper support plate 101 using the fastening material 116.

FIG. 3 exemplarily illustrates a top perspective view of an optoelectronic component 112 mounted on a heat transfer member 111 and configured to be affixed to an upper surface 103d of the lower support plate 103 through an opening 102b of the upper support plate 101 of the device component assembly 100 shown in FIGS. 1A-1B. The device components, that is, the optical components 105, 106, 107, 108, 109, and 110 and the optoelectronic component 112 of the device component assembly 100 are first mutually optically aligned to each other using an optical beam 115 as exemplarily illustrated in FIG. 1B. The optical components 105, 106, 107, 108, 109, and 110 are then affixed to the upper surface 101a of the upper support plate 101 using a fastening material 116, for example, an ultraviolet epoxy, as exemplarily illustrated in FIG. 2 and as disclosed in the detailed description of FIG. 2. The optoelectronic component, for example, the nonlinear optical crystal 112 mounted on the crystal oven 111, is then affixed to the upper surface 103d of the lower support plate 103 using the fasteners 113, for example, about four screws, through the rectangular opening 102b of the upper support plate 101 as exemplarily illustrated in FIG. 1B. Mounting the crystal oven 111 on the lower support plate 103 allows heat transfer from the crystal oven 111 to the lower support plate 103 and simultaneously maintains the optical alignment of the nonlinear optical crystal 112 mounted thereon with the other device components, for example, the optical components 109 and 110, during temperature shifting because the nonlinear optical crystal 112 has a large optical aperture. Other optoelectronic components with mechanical stages or with electronic components mounted on the lower support plate 103 are fixed with the fasteners 113 to handle their relatively large mass and weight to provide heat diffusion, thermal conductivity, and stable mechanical stability.

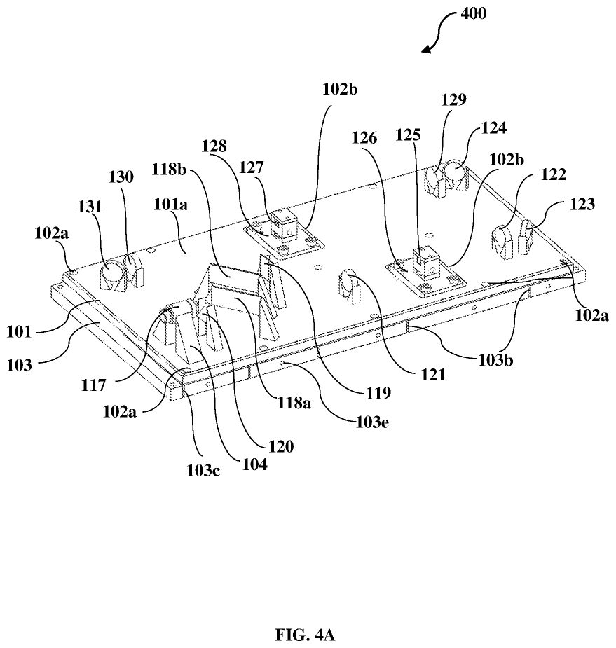

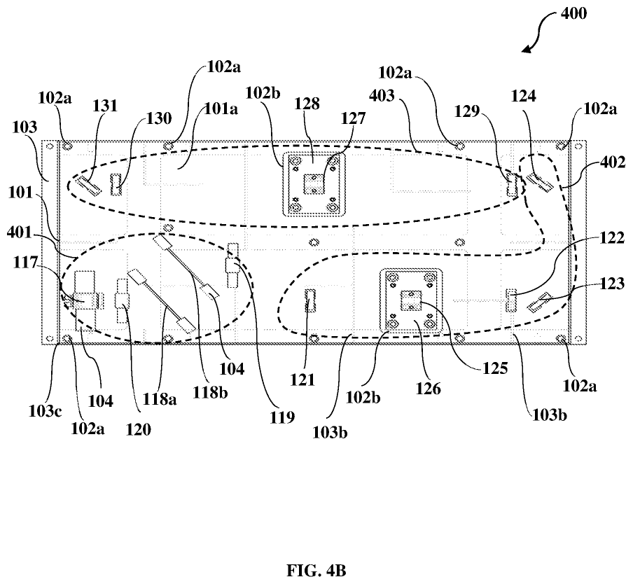

FIG. 4A exemplarily illustrates a top perspective view of a device component assembly 400 for another optoelectronic system, according to an embodiment herein. Consider an example where the device component assembly 400 is integrated in an optoelectronic system comprising a pulse compression module 401, a second-harmonic generation module 402, and a fourth-harmonic generation module 403 as indicated by dashed circles in FIG. 4B. The device component assembly 400 comprises the upper support plate 101, for example, a glass plate; a lower support plate 103, for example, a metal plate; and multiple device components, for example, 117, 118a, 118b, 119, 120, 121, 122, 123, 124, 125, 126, 127, 128, 129, 130, and 131. The dimensions of the upper support plate 101 are, for example, about 264 millimeters (mm)×140 mm×6 mm. The dimensions of the rectangular openings 102b configured in the upper support plate 101 are, for example, about 44 mm×32 mm×6 mm. The diameters of the circular openings 102a and 103a of the upper support plate 101 and the lower support plate 103 respectively are, for example, about 4.8 mm. The dimensions of the lower support plate 103 are, for example, about 280 mm×140 mm×8 mm. The gaps 103b and 103c in the lower support plate 103 are, for example, about 1 mm. The threaded hole size of the supplementary openings 103e of the lower support plate 103 is, for example, M4.

The device components, for example, 117, 118a, 118b, 119, 120, 121, 122, 123, 124, 129, 130, and 131 mounted on the upper support plate 101 are mutually optically aligned with each other and with the device components, for example, 125 and 127, mounted on the lower support plate 103 for constructing the optoelectronic system exemplarily illustrated in FIG. 4A, for implementing nonlinear optical processes, for example, pulse compression, second-harmonic generation, and fourth-harmonic generation. After mutual optical alignment, the optical components comprising, for example, a collimator 117, transmission diffraction gratings 118a and 118b, right angle prism mirrors 119 and 120, optical lenses or focus lenses 121, 122, 129, and 130, a harmonic separator 123, a reflection mirror 124, and a harmonic generator or a harmonic separator 131 are mounted and affixed to the upper surface 101a of the upper support plate 101 to maintain high stability of optical alignment during temperature shifting. The transmission diffraction gratings 118a and 118b are configured for pulse compression. Two optoelectronic components, for example, a lithium triborate (LiB₃O₅) or LBO crystal 125 mounted on a crystal oven 126 and a beta barium borate (BBO) crystal 127 mounted on a crystal oven 128 are mounted and affixed to the lower support plate 103 through the rectangular openings 102b of the upper support plate 101 for transferring heat and maintaining mechanical stability.

FIG. 4B exemplarily illustrates a top plan view of the device component assembly 400 for the optoelectronic system shown in FIG. 4A. Consider an example where the device component assembly 400 comprising the upper support plate 101 made of glass, ceramic, sapphire, or any artificial glass; the lower support plate 103 made of metal such as aluminum; optical components such as a collimator 117, transmission diffraction gratings 118a and 118b, right angle prism mirrors 119 and 120, optical lenses or focus lenses 121, 122, 129, and 130, a harmonic separator 123, a reflection mirror 124, and a harmonic generator 131; and optoelectronic components such as a lithium triborate (LiB₃O₅) or LBO crystal 125 mounted on a crystal oven 126 and a beta barium borate (BBO) crystal 127 mounted on a crystal oven 128 are integrated to form the optoelectronic system shown in FIGS. 4A-4B. The device components 117, 118a, 118b, 119, 120, 121, 122, 123, 124, 125, 126, 127, 128, 129, 130, and 131 in the device component assembly 400 are mutually optically aligned for construction of optical and optoelectronic modules, for example, a pulse compression module 401, a second-harmonic generation (SHG) module 402, and a fourth-harmonic generation (FHG) module 403 as exemplarily illustrated by dashed circles in FIG. 4B. The pulse compression module 401 processes a wide pulse, that is transmitted to achieve large radiated energy, to a narrow pulse to obtain fine-range resolution. In this example, the collimator 117 is a receptacle collimator that receives an optical beam, for example, a pulse fiber laser beam with a wavelength of about 1064 nanometers (nm) and a pulse width of about 100 picoseconds (ps) through a fiber pigtail as input. The collimator 117 collimates the pulse fiber laser beam with a beam size of, for example, about 2 millimeters (mm). The collimator 117 emits and passes the collimated laser beam to the two transmission diffraction gratings 118a and 118b, whereby the pulse width of the laser beam is compressed to about 2 ps. The laser beam that enters the transmission diffraction gratings 118a and 118b is reflected back by the right angle prism mirror 119, and re-enters the second transmission diffraction grating 118b and the first transmission grating 118a again, whereby the pulse width of the laser beam is compressed from about 80 ps to about 1.5 ps. The above disclosed operations involving the collimator 117, the transmission diffraction grating 118a and 118b, and the right angle prism mirror 119 for pulse compression constitute the pulse compression module 401 of the optoelectronic system. The right angle prism mirror 120 reflects the resulting pulse-compressed laser beam to the SHG module 402 with a connector (not shown).

The right angle prism mirror 120 passes the laser beam through the optical lens 121. The optical lens 121 focuses the laser beam into a small spot at the center of the LBO crystal 125. The LBO crystal 125 converts some of the 1064 nm wavelength of the laser beam into a wavelength of, for example, about 532 nm. The laser beam then passes through the optical lens 122. The optical lens 122 collimates the laser beam. At this point, the wavelength of the laser beam has been converted from about 1064 nm to about 532 nm. The harmonic separator 123 passes the rest of the laser beam with 1064 nm wavelength and reflects the collimated laser beam with 532 nm wavelength to the reflection mirror 124, from where the collimated laser beam with the wavelength of 532 nm passes to the fourth-harmonic generation (FHG) module 403. The above disclosed operations involving the optical lens 121, the LBO crystal 125, the optical lens 122, the harmonic separator 123, and the reflection mirror 124 for second-harmonic generation constitute the second-harmonic generation module 402 of the optoelectronic system. In the FHG module 403, the reflection mirror 124 reflects the laser beam to pass through the optical lens 129. The optical lens 129 focusses the laser beam on the BBO crystal 127, which converts the wavelength of the laser beam, for example, from about 532 nm to about 266 nm. After passing through the BBO crystal 127, the optical lens 130 collimates the laser beam to generate a collimated beam. The harmonic generator 131 allows the laser beam of about 532 nm wavelength to pass through and reflects the laser beam of about 266 nm wavelength. The operations involving the optical lens 129, the BBO crystal 127, the optical lens 130, and the harmonic generator 131 for fourth-harmonic generation constitute the FHG module 403 of the optoelectronic system.

FIG. 5 exemplarily illustrates a top perspective view of a device component assembly 500 for another optoelectronic system, according to an embodiment herein. Consider an example where the device component assembly 500 is integrated in a bow-tie structure setup for second-harmonic generation. The device component assembly 500 comprises the upper support plate 101 made of glass, ceramic, sapphire, or any artificial glass; the lower support plate 103 made of metal such as aluminum; optical components such as a collimator 132, curved mirrors 133 and 134, flat mirrors 135 and 136, and a beam splitter 140; a mechanical component such as a moving stage 137 for actuating movement of the flat mirror 136; and an optoelectronic component such as a lithium triborate (LiB₃O₅) or LBO crystal 142 mounted on a crystal oven 141. The device component assembly 500 is integrated to form the optoelectronic system shown in FIG. 5. As exemplarily illustrated in FIG. 5, in addition to the circular openings 102a at the corners of the upper support plate 101 for inserting fasteners 114 shown in FIG. 1A, and affixing the upper support plate 101 to the lower support plate 103, and the rectangular opening 102b positioned at a generally central location of the upper support plate 101 for accommodating the crystal oven 141, the upper support plate 101 further comprises a cut-out opening 102c positioned at one of the corners of the upper support plate 101 for accommodating the moving stage 137, for example, a piezo stage, on the lower support plate 103. The moving stage 137 is a nanopositioning device used to move an optical component, for example, the flat mirror 136, with nanometer precision. The moving stage 137, driven by an actuator, for example, a piezoelectric actuator, provides one or more axes of motion. In this embodiment, an optical component, for example, the flat mirror 136, is affixed to the lower support plate 103 via a mechanical component, that is, the moving stage 137. The flat mirror 136 is affixed to the moving stage 137 using a fastening material 116 exemplarily illustrated in FIG. 2. The moving stage 137 with the affixed flat mirror 136 is then affixed to the upper surface 103d of the lower support plate 103 via a mounting member 138 using fasteners 139, for example, screws with rubber or plastic washers.

The device components, for example, 132, 133, 134, 135, and 140 mounted on the upper support plate 101 are mutually optically aligned with each other and with the device components, for example, 136 and 142, mounted on the lower support plate 103 for constructing the optoelectronic system for implementing a nonlinear optical process such as second-harmonic generation. After mutual optical alignment, the optical components comprising, for example, the collimator 132, the curved mirrors 133 and 134, the flat mirror 135, and the beam splitter 140 are mounted and affixed to the upper surface 101a of the upper support plate 101 using a fastening material 116, for example, an ultraviolet epoxy, to maintain high stability of optical alignment during temperature shifting. The optical components 132, 133, 134, 135, and 140 are affixed to the upper surface 101a of the upper support plate 101 via lightweight mounting members, for example, glass blocks 104. The optical components 132, 133, 134, 135, and 140 are affixed to the glass blocks 104 using the fastening material 116. The glass blocks 104 with the affixed optical components 132, 133, 134, 135, and 140 are then affixed to the upper surface 101a of the upper support plate 101 using the fastening material 116. The LBO crystal 142 is mounted on the crystal oven 141, which is affixed to the lower support plate 103 through the rectangular opening 102b of the upper support plate 101 using fasteners 113, for example, screws, exemplarily illustrated in FIG. 3. The mounting of the LBO crystal 142 on the crystal oven 141 allows transfer of heat to the lower support plate 103 and maintenance of mechanical stability. The moving stage 137 is positioned on and attached to the mounting member 138, which is affixed to the lower support plate 103 using fasteners 139, for example, screws. The crystal oven 141 and the mounting member 138 transfer heat generated by the mounted LBO crystal 142 and the moving stage 137 respectively to the lower support plate 103. Furthermore, the crystal oven 141 allows transfer of heat generated by the mounted LBO crystal 142 to the lower support plate 103, while maintaining optical alignment of the mounted LBO crystal 142 having a large optical aperture with one or more of the other device components, for example, 133 and 134, during a temperature shift.

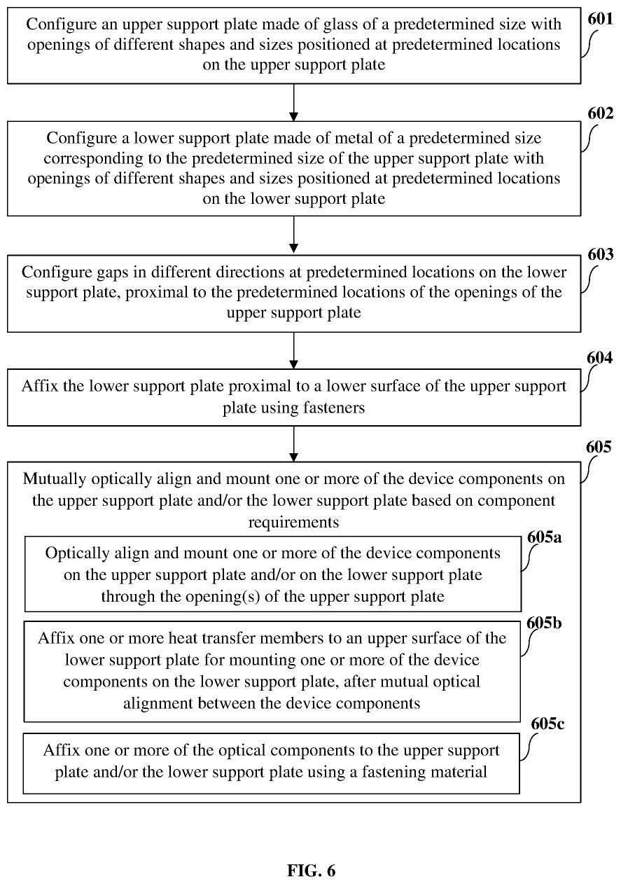

FIG. 6 illustrates a flowchart of a method for manufacturing a device component assembly, for example, 100, or 400, or 500 shown in FIGS. 1A-1C, FIGS. 4A-4B, and FIG. 5 respectively, according to an embodiment herein. In the method disclosed herein, an upper support plate 101, for example, a glass plate, of a predetermined size is configured 601 with first openings 102a, 102b, and 102c of different shapes and sizes positioned at predetermined locations on the upper support plate 101 as exemplarily illustrated in FIGS. 1A-1C, FIGS. 4A-4B, and FIG. 5. A lower support plate 103, for example, a metal plate, of a predetermined size corresponding to the predetermined size of the upper support plate 101 is configured 602 with second openings 103a and 103e of different shapes and sizes positioned at predetermined locations on the lower support plate 103 as exemplarily illustrated in FIG. 1A and FIG. 1C. Multiple gaps 103b and 103c are configured 603 in different directions at predetermined locations on the lower support plate 103, proximal to the predetermined locations of the first openings 102a of the upper support plate 101 as exemplarily illustrated in FIG. 1A and FIG. 1C. The lower support plate 103 is affixed 604 proximal to a lower surface 101b of the upper support plate 101 using the fasteners 114 exemplarily illustrated in FIG. 1A.

One or more device components comprising optical components, mechanical components, electric components, electronic components, and optoelectronic components are mutually optically aligned and mounted 605 on the upper support plate 101 and/or the lower support plate 103 based on component requirements as disclosed in the detailed descriptions of FIGS. 1A-1C, FIGS. 4A-4B, and FIG. 5. One or more of the device components are optically aligned and mounted 605a on the upper support plate 101 and/or on the lower support plate 103 through the opening(s) 102b of the upper support plate 101. In an embodiment, one or more heat transfer members, for example, the crystal oven 111 exemplarily illustrated in FIGS. 1A-1B and FIG. 3, are affixed 605b to the upper surface 103d of the lower support plate 103 for mounting one or more of the device components, for example, 112, on the lower support plate 103, after mutual optical alignment between the device components. One or more of the device components, for example, the optical components, are affixed 605c to the upper support plate 101 and/or the lower support plate 103 using a fastening material 116 exemplarily illustrated in FIG. 2. In an embodiment, one or more of the optical components, for example, 109, are affixed to the upper support plate 101 using the fastening material 116 as exemplarily illustrated in FIG. 2. In another embodiment, one or more of the optical components, for example, 136, are affixed to the lower support plate 103 via one or more mechanical components, for example, moving stages 137, as exemplarily illustrated in FIG. 5. In this embodiment, the optical component(s) is affixed to the mechanical component(s) using the fastening material 116, which is then mounted on and affixed to the lower support plate 103 using the fasteners 139. All the device components mounted on the upper support plate 101 are mutually optical aligned with each other and with all the device components mounted on the lower support plate 103 for constructing an optical system and/or an optoelectronic system for implementing multiple optical processes. The device component assembly is integrated in optical or optoelectronic modules or systems, for example, a second-harmonic generation module, a third-harmonic generation module, a fourth-harmonic generation module, an optical parametric oscillator, an optical parametric amplifier, a sum-frequency generator, a difference-frequency generator, and other optical components and modules, mechanical parts and modules, and electronic components and modules integrating systems. The device component assembly, therefore, allows implementation of multiple optical processes, for example, nonlinear optical processes such as second-harmonic generation, third-harmonic generation, fourth-harmonic generation, optical parametric oscillation, optical parametric amplification, sum-frequency generation, difference-frequency generation, etc.

Consider an example of manufacturing the device component assembly disclosed herein. A manufacturing entity cuts an upper support plate 101 made of glass, or ceramic, or sapphire, or any artificial glass, herein referred to as a “glass plate”, according the size needed. The manufacturing entity cuts one or more rectangular openings or holes 102b in a designed area of the glass plate. The manufacturing entity cuts circular openings or holes 102a at edges and corners of the glass plate. The manufacturing entity cuts a lower support plate 103 made of metal such as aluminum, stainless steel, or other metals, herein referred to as a “metal plate”, in a size equal or greater than the glass plate. The manufacturing entity then cuts narrow gaps 103b in the metal plate where there are two circular openings 102a in the glass plate to avoid tension generated by the metal plate during a temperature shift. The manufacturing entity uses screws with rubber washers or plastic washers between the glass plate and the metal plate to fasten the metal plate below the glass plate. The manufacturing entity aligns and mounts optical components on the glass plate using ultraviolet epoxy or other epoxy or glues. The manufacturing entity aligns and mounts optoelectronic components with their mounts on the metal plate using screws. The device component assembly is configured to be used in wavelength conversion, for example, second-harmonic generation (SHG), third-harmonic generation (THG), and/or fourth-harmonic generation (FHG). The device component assembly is also configured to be used in other nonlinear optical systems, for example, optical parameter oscillators, optical parameter amplifiers, etc. The device component assembly is configured to be used in any optical system or laser system as a module or with system level integration. For example, the device component assembly is configured to be used in a 266 nanometer (nm) ultraviolet (UV) laser system composed of a pulse compressor, an SHG module, and an FHG module.

In the device component assembly disclosed herein, the lower support plate 103 made of a thin metal is utilized for mounting mechanical, electric, electronic, and optoelectronic components thereon, while heavier device components are mounted on the upper support plate 101 made of a hard material, for example, glass, ceramic, sapphire, diamond, etc., thereby precluding deformation of the thin metal lower support plate 103, avoiding the resulting misalignment of the device components, and reducing the weight of the device component assembly. The use of the fastening material, for example, an epoxy, an ultraviolet epoxy, an epoxy-based composite material, a glue, etc., for affixing one or more of the optical components to the glass upper support plate 101, as opposed to using bulky metal mounts such as lens holders, reduces the size, bulkiness, and cost of the device component assembly. The device component assembly allows mounting of one or more optical components that need a heat sink and one or more optoelectronic components that need temperature control on the metal lower support plate 103. The device component assembly, therefore, manages thermal behavior, prevents misalignment of the device components, and enhances integration and performance of the device components. The increased heat diffusion capability of the metal lower support plate 103 allows optical components and electronic components, for example, a nonlinear optical crystal mounted on a crystal oven, to be mounted together in the device component assembly. Furthermore, the metal lower support plate 103 allows mounting of large metal moving stages in applications where an optical component needs a large mechanical movement using one-dimensional or two-dimensional linear moving stages. The device component assembly disclosed herein, therefore, allows multiple device components, for example, optical components, mechanical components, electric components, electronic components, and optoelectronic components, to be mutually optically aligned and mounted together on one or more support plates made of different materials based on different component requirements.

In the device component assembly disclosed herein, the optical components are aligned and fixed on the glass upper support plate 101, which has minimal thermal deformation during a temperature shift for stable optical alignment. Moreover, the optoelectronic components or the optical components with metal fixtures such as a crystal oven or a mechanical moving stage are aligned and fixed on the metal lower support plate 103, which has heat diffusion capability and mechanical stability, through the openings 102b of the glass upper support plate 101. Furthermore, there is no impact of optical misalignment between the optical components on the glass upper support plate 101 and the optoelectronic components such as periodically poled lithium niobate (PPLN) crystals, beta barium borate (BBO) crystals, etc., mounted on crystal ovens on the metal lower support plate 103 through the openings 102b of the glass upper support plate 101 during a temperature change because the optoelectronic components have a large optical effective area. Mounting of the optoelectronic components such as crystal ovens on the metal lower support plate 103 through the openings 102b of the glass upper support plate 101 allows heat generated by the optoelectronic components to be transferred to the metal lower support plate 103 easily. Because the optical components are mounted directly on the glass upper support plate 101 and affixed thereto using the fastening material, the device component assembly has a small size and is light in weight. The device component assembly and the manufacturing method thereof provide a compact, lightweight, and low-cost solution for assembling and fixing device components in a platform without heavy metal mounting members. The device component assembly has multiple applications, for example, second-harmonic generation, difference-frequency generation (DFG), sum-frequency generation (SFG), constitution of a nonlinear optics system such as an optical parametric oscillator (OPO), an optical parametric amplifier (OPA), or a general optical system that needs multiple different optical components and optoelectronic components such as nonlinear optical crystals and ovens, laser diodes with their packages, optical modulators, optical switches, piezo stages with optical components, etc.

In the device component assembly disclosed herein, the device components are configurably arranged at predetermined locations on the upper support plate 101 and the lower support plate 103 and mutually optically aligned with each other for constructing modules in complex optical and/or optoelectronic systems or for system-level construction of optical and/or optoelectronic systems. For example, the device component assembly is used for constructing an optoelectronic system involving a fiber laser configured for pumping a fluoride-based optical fiber glass such as ZrF4-BaF2-LaF3-AlF3-NaF (ZBLAN) made of zirconium, barium, lanthanum, aluminum, and sodium to generate a mid-infrared source. In another example, the device component assembly is used for constructing an optoelectronic system for second-harmonic generation and fourth-harmonic generation comprising a fiber laser, optical lenses, etc., and optoelectronic components such as nonlinear optical crystals and crystal ovens as disclosed in the detailed description of FIGS. 4A-4B. In another example, the device component assembly is used for constructing a bow-tie structure setup for second-harmonic generation comprising optical components such as lenses, mirrors, etc., and optoelectronic components such as a nonlinear optical crystal and a crystal oven, reflection mirrors, and a piezo stage as disclosed in the detailed description of FIG. 5.

The device component assembly is integrated in optical and optoelectronic systems for second-harmonic generation and fourth-harmonic generation to realize high-power green laser sources. In an exemplary implementation, the device component assembly accommodates optical components such as a 4 m ytterbium (Yb)-doped double cladding large mode area (LMA)-group distribution frame (GDF)-10/130 fiber, fiber Bragg gratings, etc., and optoelectronic components such as multimode diodes that are mutually optically aligned on the upper support plate 101 and the lower support plate 103 of the device component assembly for constructing an optoelectronic system that generates an amplified spontaneous emission (ASE) source using a fiber laser configuration comprising, for example, a 1.2-meter single mode (SM) Dysprosium ions (Dy3+) doped ZBLAN fiber with a core diameter and concentration of 12.5 micrometer (μm) and 2000 parts per million (ppm) respectively as the gain medium. In another exemplary implementation, the device component assembly is integrated in a laser system for ultrafast laser pulse compression at high average powers.

Wavelength conversion, for example, second-harmonic generation (SHG), inside a nonlinear optical crystal generates pulsed lasers, for example, at 510 nanometers (nm) from infrared lasers at 1020 nm. In another exemplary implementation, the device component assembly is integrated in an optoelectronic system where a 1020 nm pulsed fiber laser is used for high efficiency second-harmonic generation. In this exemplary implementation, the device component assembly comprises a temperature-controlled magnesium-doped periodically-poled lithium niobate (MgO:PPLN) crystal mounted on a crystal oven, which in turn is mounted on the upper surface 103d of the lower support plate 103 through an opening 102b of the upper support plate 101 of the device component assembly. The optoelectronic system constructed from this device component assembly performs second-harmonic generation in the temperature-controlled MgO:PPLN crystal to obtain an output, for example, at about 510 nm, from a high-power polarization maintaining (PM) mode-locked fiber laser at 1020 nm with 35% conversion efficiency. The resulting 510 nm laser can subsequently be used either on its own or as input to sum-frequency or frequency doubling stages to generate ultraviolet light. This optoelectronic system comprises a linear cavity all-polarization maintaining (PM) fiber-based seed followed by a pre-amplifier and two power amplifier stages. In an example, a chirped fiber Bragg grating with a center wavelength of 1020.83 nm, a 3-decibel (dB) bandwidth of 1.74 nm, a group delay dispersion of 18.5 picoseconds (ps), a dispersion of 33.35 ps/nm, and a reflectivity >99.9% is used as a reflector and a dispersion compensator. The optoelectronic system further comprises another reflector, for example, a fiber coupled semiconductor saturable absorber centered, for example, at 1064 nm with a 100 nm bandwidth. The preamplified seed pulse is 36 ps wide and has about 11 dB peak-to-pedestal ratio; the 3 dB bandwidth is 0.08 nm, corresponding to a time bandwidth product of about 1. The mode-locked laser (MLL) provides a maximum average power of, for example, about 1.2 watts (W) at a 25 megahertz (MHz) repetition rate after the power amplifiers. This optoelectronics system is used to frequency double the 1020 nm MLL, which is based on a double pass design. The MLL output is first collimated to about a 3 mm beam waist diameter and passes through a half-wave plate, which provides the polarization that allows maximum SHG conversion. The lens has a 50 mm focal length and is placed to focus the beam waist of about 32 micrometer beam waist diameter at the center of a 10 mm long MgO: PPLN crystal placed inside the crystal oven and heated to about 63.2 degree C., which corresponds to the quasi-phase matched periodicity at 1020 nm of the MgO: PPLN crystal. The mirror has a 25 mm focal length and focuses the residual fundamental beam back into the MgO: PPLN crystal for a second pass. The short-pass dichroic mirror is used first to send the fundamental beam into the MgO: PPLN crystal and to separate the fundamental and SHG beams at the output. The device component assembly provides an optimal assembly for the device components, for example, the chirped fiber Bragg grating, the reflectors, the half-wave plate, lenses, the mirrors, etc., to be mounted on and affixed to the upper support plate 101, and the MgO:PPLN crystal and its crystal oven to be mounted on and affixed to the lower support plate 103 through an opening 102b of the upper support plate 101 for construction of the optoelectronic system for high efficiency second-harmonic generation.

In another exemplary implementation, the device component assembly is integrated in an optoelectronic system for generating, for example, 134 watts (W) of a continuous-wave laser light at a wavelength of 532 nm from a fundamental power of 149 W by second-harmonic generation in an external optical resonator comprising a lithium triborate crystal. The device component assembly accommodates device components, for example, the optical resonator with the lithium triborate crystal and other optical and optoelectronic components that are mutually optically aligned with each other on the upper support plate 101 and on the lower support plate 103 through the openings 102b of the upper support plate 101 to construct the optoelectronic system that generates the 134 W of the continuous-wave laser light at a wavelength of 532 nm. High-power continuous-wave green light is useful for multiple applications, for example, titanium-sapphire or dye laser pumping and the generation of continuous-wave deep-ultraviolet radiation by second-harmonic generation, which is useful for laser guide star adaptive optics systems, fiber Bragg grating production, or semiconductor mask inspection.

In another exemplary implementation, the device component assembly is integrated in an optoelectronic system that generates a stable, high-power, picosecond ultraviolet source, for example, at 266 nm based on single-pass, two-step, fourth-harmonic generation (FHG) of a mode-locked ytterbium (Yb)-fiber laser, for example, at 79.5 MHz repetition rates in lithium borate (LiB₃O₅) or LBO and beta barium borate (β-BaB2O4) or BBO crystals, using multiple mutually optically aligned optical and optoelectronic components such as a 30-mm-long LBO crystal mounted on the lower support plate 103 through an opening 102b in the upper support plate 101 of the device component assembly. The optoelectronic system constructed therefrom generates, for example, about 9.1 watts (W) of average green power at 532 nm for 16.8 W of Yb-fiber power at a conversion efficiency of 54% in 16.2 ps pulses with a TEMOO spatial profile and passive power stability better than 0.5% rms over 16 h. The generated green radiation is then used for single-pass FHG into the ultraviolet (UV), providing as much as 1.8 W of average power at 266 nm under the optimum focusing condition in the presence of a spatial walk-off, at an overall FHG conversion efficiency of about 11%. High-power, high-repetition-rate, picosecond sources in the UV are useful for a variety of scientific, industrial, and medical applications. The combination of such single-pass schemes with fiber lasers near 1 μm is useful in the development of optical and/or optoelectronic systems that output practical UV sources using fourth-harmonic generation, due to a more compact footprint, low maintenance costs, high efficiency, long lifetime, and substantial stability, in addition to power scaling and air cooling offered by fiber lasers.

The foregoing examples and illustrative implementations of various embodiments have been provided merely for explanation and are in no way to be construed as limiting of the embodiments disclosed herein. While the embodiments have been described with reference to various illustrative implementations, drawings, and techniques, it is understood that the words, which have been used herein, are words of description and illustration, rather than words of limitation. Furthermore, although the embodiments have been described herein with reference to particular means, materials, techniques, and implementations, the embodiments herein are not intended to be limited to the particulars disclosed herein; rather, the embodiments extend to all functionally equivalent structures, methods and uses, such as are within the scope of the appended claims. It will be understood by those skilled in the art, having the benefit of the teachings of this specification, that the embodiments disclosed herein are capable of modifications and other embodiments may be effected and changes may be made thereto, without departing from the scope and spirit of the embodiments disclosed herein.

I claim:

1. A device component assembly comprising:
an upper support plate made of a first material, wherein the upper support plate comprises first openings of a plurality of shapes and sizes positioned at predetermined locations on the upper support plate;
a lower support plate made of a second material and cut in a size corresponding to a size of the upper support plate, wherein the lower support plate comprises second openings of a plurality of shapes and sizes positioned at predetermined locations on the lower support plate, and wherein the lower support plate further comprises gaps cut therein in different directions at predetermined locations proximal to the predetermined locations of the first openings of the upper support plate, and wherein the lower support plate is affixed proximal to a lower surface of the upper support plate using fasteners; and
a plurality of device components comprising optical components, mechanical components, electric components, electronic components, and optoelectronic components, wherein one or more of the device components are configured to be mutually optically aligned and mounted on one or more of the upper support plate and the lower support plate based on component requirements, and wherein one or more of the device components are mounted on the lower support plate through one or more of the first openings of the upper support plate, and wherein the one or more of the device components mounted on the upper support plate are mutually optically aligned with each other and with the one or more of the device components mounted on the lower support plate for constructing one of an optical system and an optoelectronic system for implementing a plurality of optical processes.

2. The device component assembly of claim 1, wherein the first material of the upper support plate is selected from a plurality of hard materials having low thermal expansion and that maintain mutual optical alignment of the device components during a temperature change, and wherein the hard materials comprise a glass material, an artificial glass material, a ceramic material, sapphire, quartz, and diamond, and wherein the second material of the lower support plate is a metal having a heat diffusion capability and mechanical stability.

3. The device component assembly of claim 1, wherein the gaps in the lower support plate are configured to reduce thermal expansion of the lower support plate affixed to the upper support plate, and wherein the gaps comprise at least one linear narrow gap in the lower support plate, positioned between two fixed points in the upper support plate, to avoid tension generated by the affixed lower support plate during a temperature shift.

4. The device component assembly of claim 1, further comprising one or more heat transfer members configured to be affixed to an upper surface of the lower support plate for mounting the one or more of the device components on the lower support plate, after mutual optical alignment between the device components, wherein the one or more heat transfer members are configured to transfer heat generated by the mounted one or more of the device components to the lower support plate.

5. The device component assembly of claim 1, wherein one or more of the optical components are affixed to the one or more of the upper support plate and the lower support plate using a fastening material, and wherein the fastening material is selected from one of an epoxy, an ultraviolet epoxy, an epoxy-based composite material, a glue, any adhesive material, and any soldering material.

6. The device component assembly of claim 1, wherein the mounting of the one or more of the device components on the lower support plate through the one or more of the first openings of the upper support plate allows transfer of heat generated by the one or more of the device components to the lower support plate, while maintaining mutual optical alignment of the one or more of the device components having large optical apertures with other one or more of the device components during a temperature shift.

7. The device component assembly of claim 1, wherein the component requirements comprise heat conductivity, temperature control, a heat sink, heat diffusion, mechanical movement, mechanical stability, electronic device connection, compactness, weight, thickness, space, size, rigidity, and cost.

8. A device component assembly comprising:
an upper support plate made of glass comprising first openings of a plurality of shapes and sizes positioned at predetermined locations on the upper support plate;
a lower support plate made of metal cut in a size corresponding to a size of the upper support plate, wherein the lower support plate comprises second openings of a plurality of shapes and sizes positioned at predetermined locations on the lower support plate, and wherein the lower support plate further comprises gaps cut therein in different directions at predetermined locations proximal to the predetermined locations of the first openings of the upper support plate, and wherein the lower support plate is affixed proximal to a lower surface of the upper support plate using fasteners; and
a plurality of device components comprising optical components, mechanical components, electric components, electronic components, and optoelectronic components, wherein one or more of the device components are configured to be mutually optically aligned and mounted on one or more of the upper support plate and the lower support plate based on component requirements, and wherein one or more of the device components are mounted on the lower support plate through one or more of the first openings of the upper support plate, and wherein the one or more of the device components mounted on the upper support plate are mutually optical aligned with each other and with the one or more of the device components mounted on the lower support plate for constructing one of an optical system and an optoelectronic system for implementing a plurality of optical processes.

9. The device component assembly of claim 8, wherein the gaps in the lower support plate are configured to reduce thermal expansion of the lower support plate affixed to the upper support plate, and wherein the gaps comprise at least one linear narrow gap in the lower support plate, positioned between two fixed points in the upper support plate, to avoid tension generated by the affixed lower support plate during a temperature shift.

10. The device component assembly of claim 8, wherein one or more of the optical components are mounted on the upper support plate, and wherein one or more of the mechanical components, the electric components, the electronic components, and the optoelectronic components are mounted on the lower support plate through the one or more of the first openings of the upper support plate, and wherein one or more of the mechanical components, the electric components, the electronic components, and the optoelectronic components are configured to accommodate one or more of the optical components for mounting the one or more of the optical components on the lower support plate.

11. The device component assembly of claim 8, further comprising one or more heat transfer members configured to be affixed to an upper surface of the lower support plate for mounting the one or more of the device components on the lower support plate, after mutual optical alignment between the device components, wherein the one or more heat transfer members are configured to transfer heat generated by the mounted one or more of the device components to the lower support plate.

12. The device component assembly of claim 8, wherein one or more of the optical components are affixed to the one or more of the upper support plate and the lower support plate using a fastening material, and wherein the fastening material is selected from one of an epoxy, an ultraviolet epoxy, an epoxy-based composite material, a glue, any adhesive material, and any soldering material.

13. The device component assembly of claim 8, wherein the mounting of the one or more of the device components on the lower support plate through the one or more of the first openings of the upper support plate allows transfer of heat generated by the one or more of the device components to the lower support plate, while maintaining mutual optical alignment of the one or more of the device components having large optical apertures with other one or more of the device components during a temperature shift.

14. The device component assembly of claim 8, wherein the component requirements comprise heat conductivity, temperature control, a heat sink, heat diffusion, mechanical movement, mechanical stability, electronic device connection, compactness, weight, thickness, space, size, rigidity, and cost.

15. A method for manufacturing a device component assembly, the method comprising:
configuring an upper support plate made of glass of a predetermined size with first openings of a plurality of shapes and sizes positioned at predetermined locations on the upper support plate;
configuring a lower support plate made of metal of a predetermined size corresponding to the predetermined size of the upper support plate with second openings of a plurality of shapes and sizes positioned at predetermined locations on the lower support plate;
configuring gaps in different directions at predetermined locations on the lower support plate, proximal to the predetermined locations of the first openings of the upper support plate;
affixing the lower support plate proximal to a lower surface of the upper support plate using fasteners; and
mutually optically aligning and mounting one or more of a plurality of device components comprising optical components, mechanical components, electric components, electronic components, and optoelectronic components on one or more of the upper support plate and the lower support plate based on component requirements, wherein one or more of the device components are mounted on the lower support plate through one or more of the first openings of the upper support plate, and wherein the one or more of the device components mounted on the upper support plate are mutually optical aligned with each other and with the one or more of the device components mounted on the lower support plate for constructing one of an optical system and an optoelectronic system for implementing a plurality of optical processes.

16. The method of claim 15, wherein the gaps in the lower support plate are configured to reduce thermal expansion of the lower support plate affixed to the upper support plate, and wherein the gaps comprise at least one linear narrow gap in the lower support plate, positioned between two fixed points in the upper support plate, to avoid tension generated by the affixed lower support plate during a temperature shift.

17. The method of claim 15, further comprising affixing one or more heat transfer members to an upper surface of the lower support plate for mounting the one or more of the device components on the lower support plate, after mutual optical alignment between the device components, wherein the one or more heat transfer members are configured to transfer heat generated by the mounted one or more of the device components to the lower support plate.

18. The method of claim 15, further comprising affixing one or more of the optical components to the one or more of the upper support plate and the lower support plate using a fastening material, wherein the fastening material is selected from one of an epoxy, an ultraviolet epoxy, an epoxy-based composite material, a glue, any adhesive material, and any soldering material.

19. The method of claim 15, wherein the mounting of the one or more of the device components on the lower support plate through the one or more of the first openings of the upper support plate allows transfer of heat generated by the one or more of the device components to the lower support plate, while maintaining mutual optical alignment of the one or more of the device components having large optical apertures with other one or more of the device components during a temperature shift.

20. The method of claim 15, wherein the component requirements comprise heat conductivity, temperature control, a heat sink, heat diffusion, mechanical movement, mechanical stability, electronic device connection, compactness, weight, thickness, space, size, rigidity, and cost.
